(19) United States
(12) Patent Application Publication
(10) Pub. No.: US 2026/0148768 A1
(43) Pub. Date: May 28, 2026

(54) SEMICONDUCTOR SYSTEM FOR PERFORMING SOFT-LANDING OPERATION

(71) Applicant: SK hynix Inc., Icheon-si Gyeonggi-do (KR)

(72) Inventors: Sang Hyun KU, Icheon-si Gyeonggi-do (KR); Do Hong KIM, Icheon-si Gyeonggi-do (KR); Don Hyun CHOI, Icheon-si Gyeonggi-do (KR)

(73) Assignee: SK hynix Inc., Icheon-si Gyeonggi-do (KR)

(21) Appl. No.: 19/088,452

(22) Filed: Mar. 24, 2025

(30) Foreign Application Priority Data
Nov. 22, 2024 (KR) 10-2024-0168866

(51) Int. Cl. G11C 16/08; G11C 16/04; G11C 16/30

(52) U.S. Cl. CPC G11C 16/08; G11C 16/0433; G11C 16/30

(57) ABSTRACT

Disclosed is a semiconductor system for performing a soft-landing operation that sequentially reduces the level of a word line. A semiconductor device includes a first driving element configured to drive a word line to a voltage level of a driving signal based on a word line selection signal, a second driving element configured to drive the word line based on the word line selection signal, and a third driving element configured to drive the word line based on a discharge signal.

### CROSS-REFERENCE TO RELATED APPLICATION

The present application claims priority under 35 U.S.C. § 119(a) to Korean Patent Application No. 10-2024-0168866, filed in the Korean Intellectual Property Office on Nov. 22, 2024, the entire contents of which application is incorporated herein by reference.

### BACKGROUND

The present disclosure relates to a semiconductor system for performing a soft-landing operation that sequentially reduces the level of a word line.

As the degree of integration of memory devices is increased, an interval between a plurality of word lines included in the memory device is reduced. As the interval between the plurality of word lines is reduced, a coupling effect between adjacent word lines is increased.

Whenever data are input to and output from a memory cell, the state of a word line toggles between an activation (or active) state and a deactivation state. As the coupling effect between adjacent word lines is increased as described above, a phenomenon occurs in which data of memory cells that are connected to word lines adjacent to a word line that is frequently activated are damaged. Such a phenomenon is called row hammer. Several methods for mitigating the effect of row hammer have been researched.

A soft-landing operation was proposed as one of several methods for mitigating the effect of row hammer. The soft-landing operation mitigates the effect of row hammer by maintaining the voltage level of a word line at a low voltage level for a predetermined interval before the word line is deactivated to a low voltage VBBW. However, there is a need for a method that prevents damage to data when the phenomenon occurs when the word line is in a floating state after the start of the soft-landing operation.

### SUMMARY

In an embodiment, a semiconductor device may include a first driving element configured to drive a word line to a voltage level of a driving signal based on a word line selection signal, a second driving element configured to drive the word line based on the word line selection signal, and a third driving element configured to drive the word line based on a discharge signal. The first driving element drives the word line from a high voltage to a first set voltage when the driving signal having a ground voltage is generated, after driving the word line to the high voltage when the word line selection signal is enabled and the driving signal having the high voltage is generated. The second driving element drives the word line that is driven to the first set voltage to a second set voltage when the word line selection signal is disabled. The third driving element drives the word line that is driven to the second set voltage to a low voltage when the discharge signal is enabled.

In an embodiment, a semiconductor device may include a memory region including a plurality of word lines and a row control circuit configured to activate any one of the plurality of word lines to a high voltage based on a plurality of row addresses after the start of an active operation and configured to sequentially drive the any one of the plurality of word lines, which is driven to the high voltage, to a first set voltage, a second set voltage, and a low voltage by discharging charges of the any one of the plurality of word lines based on the plurality of row addresses.

### BRIEF DESCRIPTION OF THE DRAWINGS

FIG. 1 is a block diagram illustrating a configuration of a semiconductor system according to an embodiment of the present disclosure.

FIG. 2 is a block diagram illustrating a configuration according to an embodiment of a memory device included in the semiconductor system illustrated in FIG. 1.

FIG. 3 is a block diagram illustrating a configuration according to an embodiment of a first bank included in the memory device illustrated in FIG. 2.

FIG. 4 is a block diagram illustrating a configuration according to an embodiment of a row control circuit included in the first bank illustrated in FIG. 3.

FIG. 5 is a block diagram illustrating a configuration according to an embodiment of an address control circuit included in the row control circuit illustrated in FIG. 4.

FIG. 6 is a circuit diagram illustrating a configuration according to an embodiment of an active pulse generation circuit included in the address control circuit illustrated in FIG. 5.

FIG. 7 is a block diagram illustrating a configuration according to an embodiment of a delay control circuit included in the address control circuit illustrated in FIG. 5.

FIG. 8 is a circuit diagram illustrating a configuration according to an embodiment of a third pulse control circuit included in the delay control circuit illustrated in FIG. 7.

FIG. 9 is a circuit diagram illustrating a configuration according to an embodiment of an interval signal generation circuit included in the address control circuit illustrated in FIG. 5.

FIG. 10 is a timing diagram describing an operation of the address control circuit illustrated in FIGS. 5 to 9.

FIG. 11 is a diagram illustrating a configuration according to an embodiment of an address latch circuit included in the row control circuit illustrated in FIG. 4.

FIG. 12 is a block diagram illustrating a configuration according to an embodiment of a word line control circuit included in the row control circuit illustrated in FIG. 4.

FIG. 13 is a block diagram illustrating a configuration according to an embodiment of a driving signal generation circuit included in the word line control circuit illustrated in FIG. 12.

FIG. 14 is a circuit diagram illustrating a configuration according to an embodiment of a word line selection signal generation circuit included in the driving signal generation circuit illustrated in FIG. 13.

FIG. 15 is a circuit diagram illustrating a configuration according to an embodiment of a voltage driving circuit included in the driving signal generation circuit illustrated in FIG. 13.

FIG. 16 is a circuit diagram illustrating a configuration according to an embodiment of a word line driving circuit included in the word line control circuit illustrated in FIG. 12.

FIG. 17 is a timing diagram describing an operation of a word line driving circuit according to an embodiment of the present disclosure.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

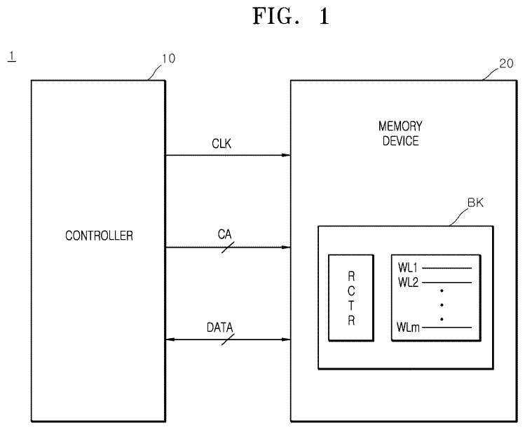

As illustrated in FIG. 1, a semiconductor system 1 according to an embodiment of the present disclosure may include a controller 10 and a memory device 20.

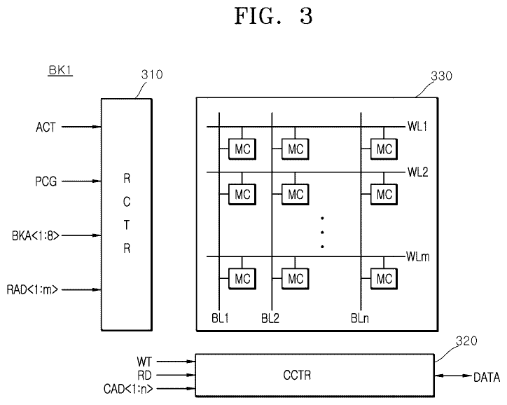

The controller 10 may transmit a clock CLK to the memory device 20. The controller 10 may transmit a command address CA to the memory device 20. The controller 10 may transmit data DATA to the memory device 20. The controller 10 may receive data DATA from the memory device 20. The clock CLK may be set as a signal that is periodically toggled in order to synchronize operations of the controller 10 and the memory device 20. The command address CA may include multiple bits and may be set as a signal including a command that controls an operation of the memory device 20 and an address that selects multiple memory cells MC included in a memory region 330 illustrated in FIG. 3. The data DATA may be set as a signal to be stored in the multiple memory cells included in the memory region 330.

The memory device 20 may include a bank BK.

The bank BK may include a row control circuit RCTR and a plurality of word lines WL1 to WLm. After the start of an active operation, the row control circuit RCTR may drive any one of the plurality of word lines WL1 to WLm to a high voltage based on the command address CA. After the start of the active operation, the row control circuit RCTR may drive any one of the plurality of word lines WL1 to WLm, which has been driven to the high voltage, to a second set voltage after driving any one of the plurality of word lines WL1 to WLm from the high voltage to a first set voltage based on the command address CA. After the start of a precharge operation, the row control circuit RCTR may drive any one of the plurality of word lines WL1 to WLm, which has been driven to the second set voltage, from the second set voltage to a low voltage.

The memory device 20 may perform an active operation and a precharge operation based on the command address CA that is received in synchronization with the clock CLK. After the start of an active operation, the memory device 20 may drive any one of the plurality of word lines WL1 to WLm to a high voltage based on the command address CA. After the start of an active operation, the memory device 20 may drive any one of the plurality of word lines WL1 to WLm, which has been driven to the high voltage, to a second set voltage after driving any one of the plurality of word lines WL1 to WLm from the high voltage to a first set voltage based on the command address CA. After the start of a precharge operation, the memory device 20 may drive any one of the plurality of word lines WL1 to WLm, which has been driven to the second set voltage, from the second set voltage to a low voltage. After the start of a write operation after an active operation, the memory device 20 may select any one of the plurality of word lines WL1 to WLm and store the data DATA in the selected word line. After the start of a read operation after an active operation, the memory device 20 may select any one of the plurality of word lines WL1 to WLm and output the data DATA stored in the selected word line.

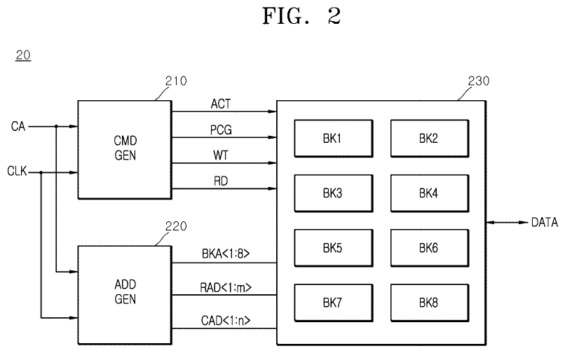

FIG. 2 is a block diagram illustrating a configuration according to an embodiment of the memory device 20 included in the semiconductor system 1. The memory device 20 may include a command generation circuit (CMD GEN) 210, an address generation circuit (ADD GEN) 220, and a memory circuit 230.

The command generation circuit 210 may generate an active command ACT that is enabled when some bits of the command address CA that are received in synchronization with the clock CLK have a logic level combination for performing an active operation. The command generation circuit 210 may generate a precharge command PCG that is enabled when some bits of the command address CA that are received in synchronization with the clock CLK have a logic level combination for performing a precharge operation. The command generation circuit 210 may generate a write command WT that is enabled when some bits of the command address CA that are received in synchronization with the clock CLK have a logic level combination for performing a write operation. The command generation circuit 210 may generate a read command RD that is enabled when some bits of the command address CA that are received in synchronization with the clock CLK have a logic level combination for performing a read operation.

The address generation circuit 220 may generate first to eighth bank addresses BKA<1:8> that are selectively enabled when some bits of the command address CA that are received in synchronization with the clock CLK have a combination for selecting any one of the first to eighth banks BK1 to BK8. For example, the address generation circuit 220 may generate the first bank address BKA<1> that is enabled when some bits of the command address CA that are received in synchronization with the clock CLK have a combination for selecting a first bank BK1.

The address generation circuit 220 may generate first to m-th row addresses RAD<1:m> that are selectively enabled when some bits of the command address CA that are received in synchronization with the clock CLK have a combination for selecting a plurality of word lines included in the first to eighth banks BK1 to BK8, that is, WL1 to WLm in FIG. 3. For example, the address generation circuit 220 may generate the first row address RAD<1> that is enabled when some bits of the command address CA that are received in synchronization with the clock CLK have a combination for selecting the first word line WL1, among the plurality of word lines included in the first to eighth banks BK1 to BK8. “m” in the m-th word line, that is, WLm in FIG. 3, and the m-th row address RAD<m> may be set as an integer greater than 0.

The address generation circuit 220 may generate first to n-th column addresses CAD<1:n> that are selectively enabled when some bits of the command address CA that are received in synchronization with the clock CLK have a combination for selecting a plurality of bit lines, that is, BL1 to BLn in FIG. 3, that are included in the first to eighth banks BK1 to BK8. For example, the address generation circuit 220 may generate the first column address CAD<1> that is enabled when some bits of the command address CA that are received in synchronization with the clock CLK have a combination for selecting the first bit line BL1, among the plurality of bit lines, that is, BL1 to BLn in FIG. 3, that are included in the first to eighth banks BK1 to BK8. “n” in the n-th bit line, that is, BLn in FIG. 3, and the n-th column address CAD<n> may be set as an integer greater than 0.

The memory circuit 230 may include the first to eighth banks BK1 to BK8. The first to eighth banks BK1 to BK8 may each include a plurality of memory cells, that is, memory cells MC in FIG. 3, that are connected between the plurality of word lines, that is, WL1 to WLm in FIG. 3, and the plurality of bit lines, that is, BL1 to BLn in FIG. 3.

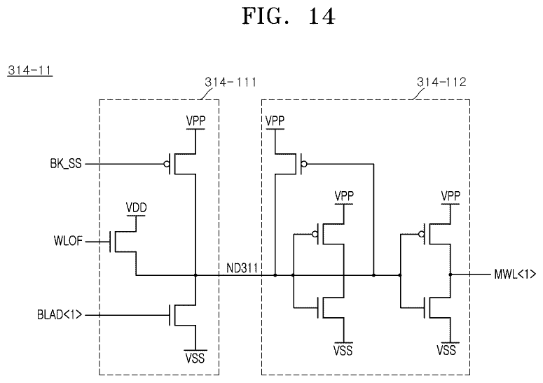

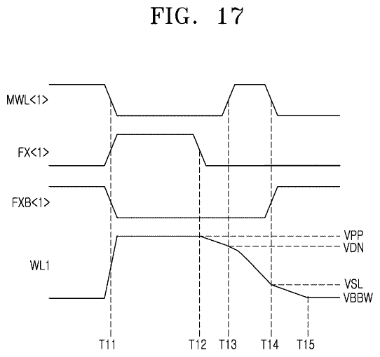

In the memory circuit 230, when the active command ACT is enabled, any one of the plurality of word lines, that is, WL1 to WLm in FIG. 3, may be selectively activated. When the active command ACT is enabled, the memory circuit 230 may drive any one of the first to m-th word lines WL1 to WLm to a high voltage, that is, VPP in FIG. 14, based on the first to eighth bank addresses BKA<1:8> and the first to m-th row addresses RAD<1:m>. The memory circuit 230 may drive any one of the first to m-th word lines WL1 to WLm, which has been driven to the high voltage, that is, VPP in FIG. 14, to a first set voltage, that is, VDN in FIG. 17, based on the first to eighth bank addresses BKA<1:8> and the first to m-th row addresses RAD<1:m>. The memory circuit 230 may drive any one of the first to m-th word lines WL1 to WLm, which has been driven to the first set voltage, that is, VDN in FIG. 17, to a second set voltage, that is, VSL in FIG. 17, based on the first to eighth bank addresses BKA<1:8> and the first to m-th row addresses RAD<1:m>. When the precharge command PCG is enabled, the memory circuit 230 may drive any one of the first to m-th word lines WL1 to WLm, which has been driven to the second set voltage, that is, VSL in FIG. 17, to a low voltage, that is, VBBW in FIG. 17, based on the first to eighth bank addresses BKA<1:8> and the first to m-th row addresses RAD<1:m>.

In the memory circuit 230, when the write command WT is enabled, any one of the plurality of bit lines, that is, BL1 to BLn in FIG. 3, may be selectively activated based on the first to n-th column addresses CAD<1:n>. The memory circuit 230 may store the data DATA in the memory cell, that is, MC in FIG. 3, which is connected to a word line that is activated and a bit line that is activated when the write command WT is enabled.

In the memory circuit 230, when the read command RD is enabled, any one of the plurality of bit lines, that is, BL1 to BLn in FIG. 3, may be selectively activated based on the first to n-th column addresses CAD<1:n>. The memory circuit 230 may output the data DATA stored in the memory cell, that is, MC in FIG. 3, which is connected to a word line that is activated and a bit line that is activated when the read command RD is enabled.

The memory circuit 230 may perform a precharge operation that drives the plurality of bit lines, that is, BL1 to BLn in FIG. 3, to a set voltage level when the precharge command PCG is enabled.

FIG. 3 is a block diagram illustrating a configuration according to an embodiment of the first bank BK1 included in the memory device 20. The first bank BK1 may include a row control circuit (RCTR) 310, a column control circuit (CCTR) 320, and a memory region 330.

When the active command ACT is enabled, the row control circuit 310 may activate any one of the first to m-th word lines WL1 to WLm by driving the any one word line to the high voltage, that is, VPP in FIG. 14, based on the first bank address BKA<1> and the first to m-th row addresses RAD<1:m>. The row control circuit 310 may drive any one of the first to m-th word lines WL1 to WLm, which has been driven to the high voltage, that is, VPP in FIG. 14, to the first set voltage, that is, VDN in FIG. 17, based on the first bank address BKA<1> and the first to m-th row addresses RAD<1:m>. The row control circuit 310 may drive any one of the first to m-th word lines WL1 to WLm, which has been driven to the first set voltage, that is, VDN in FIG. 17, to the second set voltage, that is, VSL in FIG. 17, based on the first bank address BKA<1> and the first to m-th row addresses RAD<1:m>. When the precharge command PCG is enabled, the row control circuit 310 may drive any one of the first to m-th word lines WL1 to WLm, which has been driven to the second set voltage, that is, VSL in FIG. 17, to the low voltage, that is, VBBW in FIG. 17, based on the first bank address BKA<1> and the first to m-th row addresses RAD<1:m>.

When the write command WT is enabled, the column control circuit 320 may selectively activate any one of the first to n-th bit lines BL1 to BLn based on the first to n-th column addresses CAD<1:n>. When the write command WT is enabled, the column control circuit 320 may store the data DATA in the memory cell MC that is connected to a word line that is activated and a bit line that is activated.

When the read command RD is enabled, the column control circuit 320 may selectively activate any one of the first to n-th bit lines BL1 to BLn based on the first to n-th column addresses CAD<1:n>. When the read command RD is enabled, the column control circuit 320 may output the data DATA stored in the memory cell MC that is connected to a word line that is activated and a bit line that is activated.

The memory region 330 may include the first to m-th word lines WL1 to WLm, the first to n-th bit lines BL1 to BLn, and the plurality of memory cells MC that is connected between the first to m-th word lines WL1 to WLm and the first to n-th bit lines BL1 to BLn. After the start of a write operation, the memory region 330 may store the data DATA in the memory cell MC that is connected to a word line that is activated, among the first to m-th word lines WL1 to WLm, and a bit line that is activated, among the first to n-th bit lines BL1 to BLn, under the control of the row control circuit 310 and the column control circuit 320. After the start of a read operation, the memory region 330 may output the data DATA stored in the memory cell MC that is connected to a word line that is activated, among the first to m-th word lines WL1 to WLm, and a bit line that is activated, among the first to n-th bit lines BL1 to BLn, under the control of the row control circuit 310 and the column control circuit 320.

Each of the second to eighth banks BK2 to BK8, illustrated in FIG. 2, is implemented with the same configuration as the first bank BK1, illustrated in FIG. 3, and may perform the same operation as the first bank BK1 illustrated in FIG. 3, and thus a detailed description thereof is omitted.

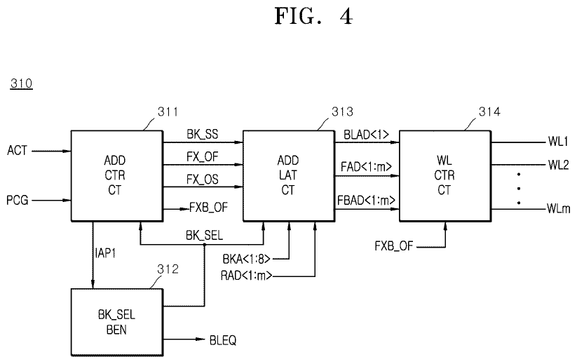

FIG. 4 is a block diagram illustrating a configuration according to an embodiment of the row control circuit 310 included in the first bank BK1. The row control circuit 310 may include an address control circuit (ADD CTR CT) 311, a bank selection signal generation circuit (BK_SEL BEN) 312, an address latch circuit (ADD LAT CT) 313, and a word line control circuit (WL CTR CT) 314.

Based on the active command ACT and the precharge command PCG, the address control circuit 311 may generate a first internal active pulse IAP1 having an adjusted pulse width. Based on the first internal active pulse IAP1 and a bank selection signal BK_SEL, the address control circuit 311 may generate a bank interval signal BK_SS, a first voltage interval signal FX_OF, a second voltage interval signal FX_OS, and an inversion voltage interval signal FXB_OF, each one having an adjusted pulse width adjusted.

The bank selection signal generation circuit 312 may generate the bank selection signal BK_SEL and an equalization signal BLEQ, based on the first internal active pulse IAP1. The bank selection signal generation circuit 312 may generate the bank selection signal BK_SEL by adjusting the pulse width of the first internal active pulse IAP1. When the bank selection signal BK_SEL is disabled, the bank selection signal generation circuit 312 may generate the equalization signal BLEQ that is enabled. The equalization signal BLEQ may be set as a signal that precharges the first to n-th bit lines BL1 to BLn by being supplied to a sense amplifier included in the column control circuit 320.

The address latch circuit 313 may generate a first bank latch address BLAD<1> based on the first bank address BKA<1> in an interval in which the bank interval signal BK_SS is enabled. The address latch circuit 313 may generate first to m-th driving addresses FAD<1:m> based on the bank selection signal BK_SEL, the bank interval signal BK_SS, the first voltage interval signal FX_OF, and the first to m-th row addresses RAD<1:m>. The address latch circuit 313 may generate first to m-th inversion driving addresses FBAD<1:m> based on the bank selection signal BK_SEL, the bank interval signal BK_SS, the second voltage interval signal FX_OS, the inversion voltage interval signal FXB_OF, and the first to m-th row addresses RAD<1:m>.

When the first bank latch address BLAD<1> is enabled, the word line control circuit 314 may activate any one of the first to m-th word lines WL1 to WLm based on the first to m-th driving addresses FAD<1:m> and the first to m-th inversion driving addresses FBAD<1:m.

When the first bank latch address BLAD<1> is enabled, the word line control circuit 314 may activate any one of the first to m-th word lines WL1 to WLm by driving the any one word line to the high voltage, that is, VPP in FIG. 14, based on the inversion voltage interval signal FXB_OF, the first to m-th driving addresses FAD<1:m>, and the first to m-th inversion driving addresses FBAD<1:m>. When the first bank latch address BLAD<1> is enabled, the word line control circuit 314 may drive any one of the first to m-th word lines WL1 to WLm, which has been driven to the high voltage, that is, VPP in FIG. 14, to the first set voltage, that is, VDN in FIG. 17, based on the inversion voltage interval signal FXB_OF, the first to m-th driving addresses FAD<1:m>, and the first to m-th inversion driving addresses FBAD<1:m>. When the first bank latch address BLAD<1> is enabled, the word line control circuit 314 may drive any one of the first to m-th word lines WL1 to WLm, which has been driven to the second set voltage, that is, VSL in FIG. 17, to the first set voltage, that is, VDN in FIG. 17, based on the inversion voltage interval signal FXB_OF, the first to m-th driving addresses FAD<1:m>, and the first to m-th inversion driving addresses FBAD<1:m>. When the first bank latch address BLAD<1> is enabled, the word line control circuit 314 may drive any one of the first to m-th word lines WL1 to WLm, which has been driven to the second set voltage, that is, VSL in FIG. 17, to the low voltage, that is, VBBW in FIG. 17, based on the inversion voltage interval signal FXB_OF, the first to m-th driving addresses FAD<1:m>, and the first to m-th inversion driving addresses FBAD<1:m>.

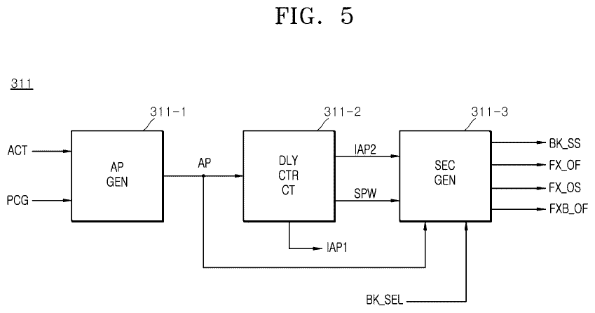

FIG. 5 is a block diagram illustrating a configuration according to an embodiment of the address control circuit 311 included in the row control circuit 310. The address control circuit 311 may include an active pulse generation circuit (AP GEN) 311-1, a delay control circuit (DLY CTR CT) 311-2, and an interval signal generation circuit (SEC GEN) 311-3.

The active pulse generation circuit 311-1 may generate an active pulse AP based on the active command ACT and the precharge command PCG. The active pulse generation circuit 311-1 may generate the active pulse AP having a pulse width from a time at which the active command ACT is enabled to a time at which the precharge command PCG is enabled.

The delay control circuit 311-2 may generate the first internal active pulse IAP1, a second internal active pulse IAP2, and a synthesis pulse signal SPW, based on the active pulse AP. The delay control circuit 311-2 may generate the first internal active pulse IAP1 by delaying the active pulse AP and adjusting the pulse width of the active pulse AP. The delay control circuit 311-2 may generate the second internal active pulse IAP2 by delaying the first internal active pulse IAP1 and adjusting the pulse width of the first internal active pulse IAP1. The delay control circuit 311-2 may generate the synthesis pulse signal SPW by synthesizing the first internal active pulse IAP1 and the second internal active pulse IAP2.

The interval signal generation circuit 311-3 may generate the bank interval signal BK_SS, the first voltage interval signal FX_OF, the second voltage interval signal FX_OS, and the inversion voltage interval signal FXB_OF, based on the bank selection signal BK_SEL, the active pulse AP, the second internal active pulse IAP2, and the synthesis pulse signal SPW. The interval signal generation circuit 311-3 may generate the bank interval signal BK_SS based on the bank selection signal BK_SEL and the synthesis pulse signal SPW. The interval signal generation circuit 311-3 may generate the first voltage interval signal FX_OF by buffering the active pulse AP. The interval signal generation circuit 311-3 may generate the second voltage interval signal FX_OS by buffering the second internal active pulse IAP2. The interval signal generation circuit 311-3 may generate the inversion voltage interval signal FXB_OF by buffering the second internal active pulse IAP2.

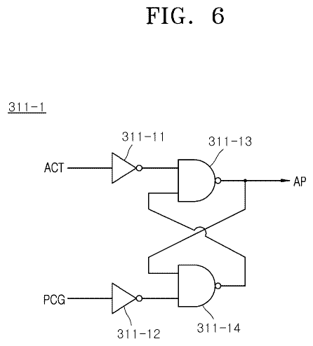

FIG. 6 is a circuit diagram illustrating a configuration according to an embodiment of the active pulse generation circuit 311-1 included in the address control circuit 311.

The active pulse generation circuit 311-1 may be implemented with inverters 311-11 and 311-12 and NAND gates 311-13 and 311-14. The active pulse generation circuit 311-1 may generate the active pulse AP at a logic high level when the active command ACT is enabled to a logic high level. The active pulse generation circuit 311-1 may generate the active pulse AP at a logic low level when the precharge command PCG is enabled to a logic high level.

The active pulse generation circuit 311-1 may generate the active pulse AP having a logic high level from a time at which the active command ACT is enabled to a logic high level to a time at which the precharge command PCG is enabled to a logic high level.

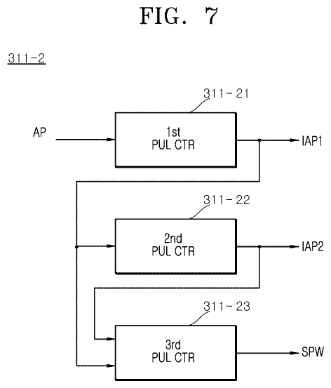

FIG. 7 is a block diagram illustrating a configuration according to an embodiment of the delay control circuit 311-2 included in the address control circuit 311. The delay control circuit 311-2 may include a first pulse control circuit (1^{st} PUL CTR) 311-21, a second pulse control circuit (2^{nd} PUL CTR) 311-22, and a third pulse control circuit (3^{rd} PUL CTR) 311-23.

The first pulse control circuit 311-21 may generate the first internal active pulse IAP1 based on the active pulse AP. The first pulse control circuit 311-21 may generate the first internal active pulse IAP1 by delaying the active pulse AP and adjusting the pulse width of the active pulse AP.

The second pulse control circuit 311-22 may generate the second internal active pulse IAP2 based on the first internal active pulse IAP1. The second pulse control circuit 311-22 may generate the second internal active pulse IAP2 by delaying the first internal active pulse IAP1 and adjusting the pulse width of the first internal active pulse IAP1.

The third pulse control circuit 311-23 may generate the synthesis pulse signal SPW, based on the first internal active pulse IAP1 and the second internal active pulse IAP2. The third pulse control circuit 311-23 may generate the synthesis pulse signal SPW by synthesizing the first internal active pulse IAP1 and the second internal active pulse IAP2.

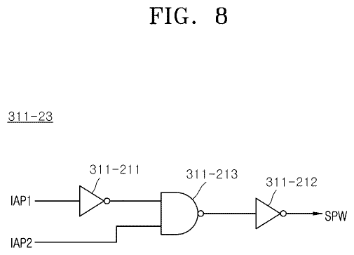

FIG. 8 is a circuit diagram illustrating a configuration according to an embodiment of the third pulse control circuit 311-23 included in the delay control circuit 311-2.

The third pulse control circuit 311-23 may be implemented with inverters 311-211 and 311-212 and a NAND gate 311-213. The third pulse control circuit 311-23 may generate the synthesis pulse signal SPW by inverting and buffering the first internal active pulse IAP1 when the second internal active pulse IAP2 is at a logic high level. The third pulse control circuit 311-23 may generate the synthesis pulse signal SPW having a logic low level when the first internal active pulse IAP1 is at a logic high level. The third pulse control circuit 311-23 may generate the synthesis pulse signal SPW having a logic low level when the second internal active pulse IAP2 is at a logic low level. The third pulse control circuit 311-23 may generate the synthesis pulse signal SPW having a logic high level, when the first internal active pulse IAP1 is at a logic low level and the second internal active pulse IAP2 is at a logic high level.

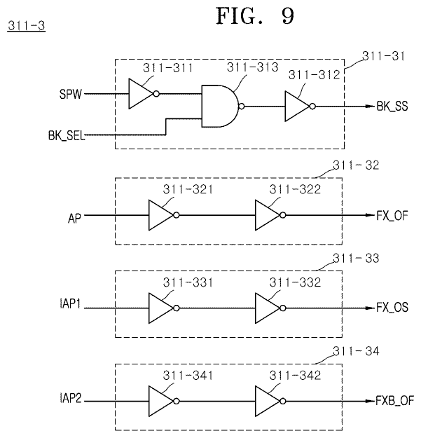

FIG. 9 is a circuit diagram illustrating a configuration according to an embodiment of the interval signal generation circuit 311-3 included in the address control circuit 311. The interval signal generation circuit 311-3 may include a first logic circuit 311-31, a second logic circuit 311-32, a third logic circuit 311-33, and a fourth logic circuit 311-34.

The first logic circuit 311-31 may be implemented with inverters 311-311 and 311-312 and a NAND gate 311-313. When the bank selection signal BK_SEL is at a logic high level, the first logic circuit 311-31 may generate the bank interval signal BK_SS by inverting and buffering the synthesis pulse signal SPW. The first logic circuit 311-31 may generate the bank interval signal BK_SS having a logic low level when the synthesis pulse signal SPW is at a logic high level. The first logic circuit 311-31 may generate the bank interval signal BK_SS having a logic low level when the bank selection signal BK_SEL is at a logic low level. When the synthesis pulse signal SPW is at a logic low level in an interval in which the bank selection signal BK_SEL is at a logic high level, the first logic circuit 311-31 may generate the bank interval signal BK_SS having a logic high level.

The second logic circuit 311-32 may be implemented with inverters 311-321 and 311-322. The second logic circuit 311-32 may generate the first voltage interval signal FX_OF by buffering the active pulse AP. The second logic circuit 311-32 may generate the first voltage interval signal FX_OF having a logic high level when the active pulse AP is at a logic high level. The second logic circuit 311-32 may generate the first voltage interval signal FX_OF having a logic low level when the active pulse AP is at a logic low level.

The third logic circuit 311-33 may be implemented with inverters 311-331 and 311-332. The third logic circuit 311-33 may generate the second voltage interval signal FX_OS by buffering the second internal active pulse IAP2. The third logic circuit 311-33 may generate the second voltage interval signal FX_OS having a logic high level when the second internal active pulse IAP2 is at a logic high level. The third logic circuit 311-33 may generate the second voltage interval signal FX_OS having a logic low level when the second internal active pulse IAP2 is at a logic low level.

The fourth logic circuit 311-34 may be implemented with inverters 311-341 and 311-342. The fourth logic circuit 311-34 may generate the inversion voltage interval signal FXB_OF by buffering the second internal active pulse IAP2. The fourth logic circuit 311-34 may generate the inversion voltage interval signal FXB_OF having a logic high level when the second internal active pulse IAP2 is at a logic high level. The fourth logic circuit 311-34 may generate the inversion voltage interval signal FXB_OF having a logic low level when the second internal active pulse IAP2 is at a logic low level.

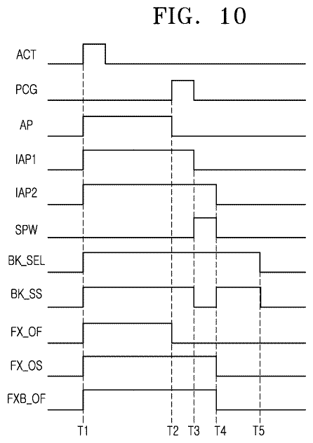

FIG. 10 is a timing diagram describing an operation of the address control circuit 311 according to an embodiment of the present disclosure.

At timing T1, the active pulse generation circuit 311-1 may generate the active pulse AP having a logic high level when the active command ACT is enabled to a logic high level.

At timing T2, the active pulse generation circuit 311-1 may generate the active pulse AP having a logic low level when the precharge command PCG is enabled to a logic high level.

That is, the active pulse generation circuit 311-1 may generate the active pulse AP having a pulse width at a logic high level from a time at which the active command ACT is enabled to a time at which the precharge command PCG is enabled.

At timing T1, the first pulse control circuit 311-21 of the delay control circuit 311-2 may generate the first internal active pulse IAP1 having a logic high level when the active pulse AP is enabled to a logic high level.

At timing T3, the first pulse control circuit 311-21 of the delay control circuit 311-2 may generate the first internal active pulse IAP1 having a logic low level by delaying the active pulse AP having a logic low level, which has been generated at timing T2.

That is, the first pulse control circuit 311-21 of the delay control circuit 311-2 may generate the first internal active pulse IAP1 by delaying the active pulse AP and adjusting the pulse width of the active pulse AP.

At timing T1, the second pulse control circuit 311-22 of the delay control circuit 311-2 may generate the second internal active pulse IAP2 having a logic high level when the first internal active pulse IAP1 is enabled to a logic high level.

At timing T4, the second pulse control circuit 311-22 of the delay control circuit 311-2 may generate the second internal active pulse IAP2 having a logic low level by delaying the first internal active pulse IAP1 having a logic low level, which has been generated at timing T3.

That is, the second pulse control circuit 311-22 of the delay control circuit 311-2 may generate the second internal active pulse IAP2 by delaying the first internal active pulse IAP1 and adjusting the pulse width of the first internal active pulse IAP1.

At timing T3, when the first internal active pulse IAP1 is at a logic low level and the second internal active pulse IAP2 is at a logic high level, the third pulse control circuit 311-23 of the delay control circuit 311-2 may generate the synthesis pulse signal SPW having a logic high level.

At timing T4, when the first internal active pulse IAP1 is at a logic low level and the second internal active pulse IAP2 is at a logic low level, the third pulse control circuit 311-23 of the delay control circuit 311-2 may generate the synthesis pulse signal SPW having a logic low level.

That is, the third pulse control circuit 311-23 of the delay control circuit 311-2 may generate the synthesis pulse signal SPW by synthesizing the first internal active pulse IAP1 and the second internal active pulse IAP2.

At timing T1, the bank selection signal generation circuit 312 may generate the bank selection signal BK_SEL having a logic high level when the first internal active pulse IAP1 is enabled to a logic high level.

At timing T5, the bank selection signal generation circuit 312 may generate the bank selection signal BK_SEL having a logic low level by delaying the first internal active pulse IAP1 having a logic low level, which has been generated at timing T3.

That is, the bank selection signal generation circuit 312 may generate the bank selection signal BK_SEL by delaying the first internal active pulse IAP1 and adjusting the pulse width of the first internal active pulse IAP1.

At timing T1, the first logic circuit 311-31 of the interval signal generation circuit 311-3 generates the bank interval signal BK_SS having a logic high level by inverting and buffering the synthesis pulse signal SPW having a logic low level when the bank selection signal BK_SEL is at a logic high level.

At timing T3, the first logic circuit 311-31 of the interval signal generation circuit 311-3 generates the bank interval signal BK_SS having a logic low level by inverting and buffering the synthesis pulse signal SPW having a logic high level when the bank selection signal BK_SEL is at a logic high level.

At timing T4, when the bank selection signal BK_SEL is at a logic high level, the first logic circuit 311-31 of the interval signal generation circuit 311-3 may generate the bank interval signal BK_SS having a logic high level by inverting and buffering the synthesis pulse signal SPW having a logic low level.

At timing T5, when the bank selection signal BK_SEL is at a logic high level, the first logic circuit 311-31 of the interval signal generation circuit 311-3 may generate the bank interval signal BK_SS having a logic low level by inverting and buffering the synthesis pulse signal SPW having a logic high level.

That is, the first logic circuit 311-31 of the interval signal generation circuit 311-3 may generate the bank interval signal BK_SS having a logic high level when the synthesis pulse signal SPW is at a logic low level in an interval in which the bank selection signal BK_SEL is at a logic high level.

At timing T1, the second logic circuit 311-32 of the interval signal generation circuit 311-3 may generate the first voltage interval signal FX_OF having a logic high level when the active pulse AP is at a logic high level.

At timing T2, the second logic circuit 311-32 of the interval signal generation circuit 311-3 may generate the first voltage interval signal FX_OF having a logic low level when the active pulse AP is at a logic low level.

That is, the second logic circuit 311-32 of the interval signal generation circuit 311-3 may generate the first voltage interval signal FX_OF having a logic high level when the active pulse AP is at a logic high level.

At timing T1, the third logic circuit 311-33 of the interval signal generation circuit 311-3 may generate the second voltage interval signal FX_OS having a logic high level when the second internal active pulse IAP2 is at a logic high level.

At timing T4, the third logic circuit 311-33 of the interval signal generation circuit 311-3 may generate the second voltage interval signal FX_OS having a logic low level when the second internal active pulse IAP2 is at a logic low level.

That is, the second logic circuit 311-32 of the interval signal generation circuit 311-3 may generate the second voltage interval signal FX_OS having a logic high level when the second internal active pulse IAP2 is at a logic high level.

At timing T1, the fourth logic circuit 311-34 of the interval signal generation circuit 311-3 may generate the inversion voltage interval signal FXB_OF having a logic high level when the second internal active pulse IAP2 is at a logic high level.

At timing T4, the fourth logic circuit 311-34 of the interval signal generation circuit 311-3 may generate the inversion voltage interval signal FXB_OF having a logic low level when the second internal active pulse IAP2 is at a logic low level.

That is, the fourth logic circuit 311-34 of the interval signal generation circuit 311-3 may generate the inversion voltage interval signal FXB_OF having a logic high level when the second internal active pulse IAP2 is at a logic high level.

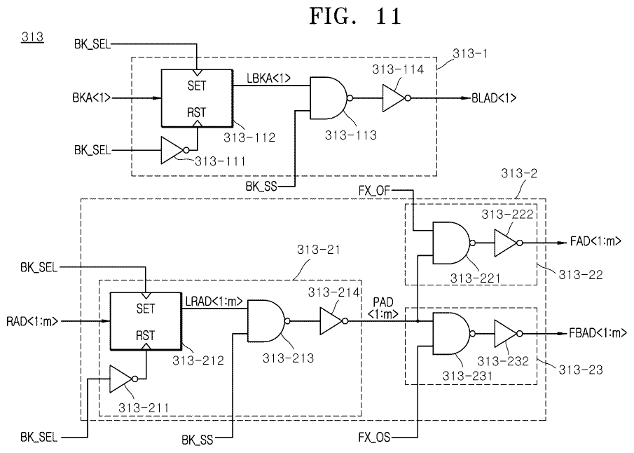

FIG. 11 is a diagram illustrating a configuration according to an embodiment of the address latch circuit 313 included in the row control circuit 310. The address latch circuit 313 may include a first address latch circuit 313-1 and a second address latch circuit 313-2.

The first address latch circuit 313-1 may be implemented with an inverter 313-111, a latch 313-112, a NAND gate 313-113, and an inverter 313-114. The inverter 313-111 may output the bank selection signal BK_SEL by inverting and buffering the bank selection signal BK_SEL. The latch 313-112 may generate the first latch address LBKA<1> by latching the first bank address BKA<1> when the bank selection signal BK_SEL is at a logic high level. The latch 313-112 may initialize the first latch address LBKA<1> to a logic low level when the output signal of the inverter 313-111 is at a logic high level. The NAND gate 313-113 and the inverter 313-114 may generate the first bank latch address BLAD<1> by buffering the first latch address LBKA<1> in an interval in which the bank interval signal BK_SS is at a logic high level. The NAND gate 313-113 and the inverter 313-114 may generate the first bank latch address BLAD<1> having a logic low level when the bank interval signal BK_SS is at a logic low level. The first address latch circuit 313-1 may generate the first latch address LBKA<1> by latching the first bank address BKA<1> in an interval in which the bank selection signal BK_SEL is at a logic high level. The first address latch circuit 313-1 may generate the first bank latch address BLAD<1> by buffering the first latch address LBKA<1> in an interval in which the bank interval signal BK_SS is at a logic high level.

The second address latch circuit 313-2 may include a pre-address generation circuit 313-21, a driving address generation circuit 313-22, and an inversion driving address generation circuit 313-23.

The pre-address generation circuit 313-21 may be implemented with an inverter 313-211, a latch 313-212, a NAND gate 313-213, and an inverter 313-214. The inverter 313-211 may output the bank selection signal BK_SEL by inverting and buffering the bank selection signal BK_SEL. The latch 313-212 may generate first to m-th latch row addresses LRAD<1:m> by latching the first to m-th row addresses RAD<1:m> when the bank selection signal BK_SEL is at a logic high level. The latch 313-212 may initialize the first to m-th latch row addresses LRAD<1:m> to a logic low level when the output signal of the inverter 313-211 is at a logic high level. The NAND gate 313-213 and the inverter 313-214 may generate first to m-th pre-addresses PAD<1:m> by buffering the first to m-th latch row addresses LRAD<1:m> in an interval in which the bank interval signal BK_SS is at a logic high level. The NAND gate 313-213 and the inverter 313-214 may generate the first to m-th pre-addresses PAD<1:m> having a logic low level when the bank interval signal BK_SS is at a logic low level. The pre-address generation circuit 313-21 may generate the first to m-th latch row addresses LRAD<1:m> by latching the first to m-th row addresses RAD<1:m> in an interval in which the bank selection signal BK_SEL is at a logic high level. The pre-address generation circuit 313-21 may generate the first to m-th pre-addresses PAD<1:m> by buffering the first to m-th latch row addresses LRAD<1:m> in an interval in which the bank interval signal BK_SS is at a logic high level.

The driving address generation circuit 313-22 may be implemented with a NAND gate 313-221 and an inverter 313-222. The driving address generation circuit 313-22 may generate the first to m-th driving addresses FAD<1:m> by buffering the first to m-th pre-addresses PAD<1:m> in an interval in which the first voltage interval signal FX_OF is at a logic high level. The driving address generation circuit 313-22 may generate the first to m-th driving addresses FAD<1:m> having a logic low level in an interval in which the first voltage interval signal FX_OF is at a logic low level.

The inversion driving address generation circuit 313-23 may be implemented with a NAND gate 313-231 and an inverter 313-232. The inversion driving address generation circuit 313-23 may generate the first to m-th inversion driving addresses FBAD<1:m> by buffering the first to m-th pre-addresses PAD<1:m> in an interval in which the second voltage interval signal FX_OS is at a logic high level. The inversion driving address generation circuit 313-23 may generate the first to m-th inversion driving addresses FBAD<1:m> having a logic low level in an interval in which the second voltage interval signal FX_OS is at a logic low level.

The second address latch circuit 313-2 has been illustrated as a single circuit. However, the second address latch circuit may be implemented with m circuits, the number of which is the same as the number of bits of each of the first to m-th row addresses RAD<1:m>, the first to m-th driving addresses FAD<1:m>, and the first to m-th inversion driving addresses FBAD<1:m>.

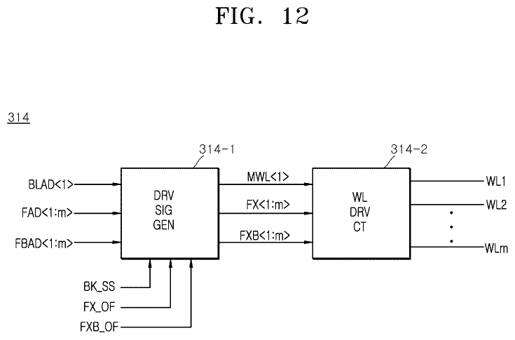

FIG. 12 is a block diagram illustrating a configuration according to an embodiment of the word line control circuit 314 included in the row control circuit 310. The word line control circuit 314 may include a driving signal generation circuit (DRV SIG GEN) 314-1 and a word line driving circuit (WL DRV CT) 314-2.

The driving signal generation circuit 314-1 may generate a first word line selection signal MWL<1> based on the bank interval signal BK_SS and the first bank latch address BLAD<1>. When the bank interval signal BK_SS is enabled to a logic high level and the first bank latch address BLAD<1> is enabled to a logic high level, the driving signal generation circuit 314-1 may generate the first word line selection signal MWL<1> that is enabled to a logic low level.

The driving signal generation circuit 314-1 may generate first to m-th driving signals FX<1:m> based on the first voltage interval signal FX_OF and the first to m-th driving addresses FAD<1:m>. The driving signal generation circuit 314-1 may generate the first to m-th driving signals FX<1:m> selectively having the voltage level of the high voltage, that is, VPP in FIG. 14, based on the first voltage interval signal FX_OF being enabled to a logic high level and the first to m-th driving addresses FAD<1:m>. The driving signal generation circuit 314-1 may generate the first to m-th driving signals FX<1:m> having a voltage level from the voltage level of the high voltage, that is, VPP in FIG. 14, to the voltage level of the ground voltage, that is, VSS in FIG. 14, based on the first to m-th driving addresses FAD<1:m>.

The driving signal generation circuit 314-1 may generate first to m-th discharge signals FXB<1:m> based on the inversion voltage interval signal FXB_OF and the first to m-th inversion driving addresses FBAD<1:m>. The driving signal generation circuit 314-1 may generate the first to m-th discharge signals FXB<1:m> selectively having the voltage level of the high voltage, that is, VPP in FIG. 14, based on the inversion voltage interval signal FXB_OF and the first to m-th inversion driving addresses FBAD<1:m>. The driving signal generation circuit 314-1 may generate the first to m-th discharge signals FXB<1:m> having a voltage level from the voltage level of the ground voltage, that is, VSS in FIG. 14, to the voltage level of the high voltage, that is, VPP in FIG. 14, based on the inversion voltage interval signal FXB_OF and the first to m-th inversion driving addresses FBAD<1:m>.

The word line driving circuit 314-2 may activate any one of the first to m-th word lines WL1 to WLm to the high voltage, that is, VPP in FIG. 14, based on the first word line selection signal MWL<1>, the first to m-th driving signals FX<1:m>, and the first to m-th discharge signals FXB<1:m>. The word line driving circuit 314-2 may drive a word line that is activated, among the first to m-th word lines WL1 to WLm, from the high voltage, that is, VPP in FIG. 14, to the first set voltage, that is, VDN in FIG. 17, based on the first word line selection signal MWL<1>, the first to m-th driving signals FX<1:m>, and the first to m-th discharge signals FXB<1:m>. The word line driving circuit 314-2 may drive a word line that has been driven to the first set voltage, that is, VDN in FIG. 17, among the first to m-th word lines WL1 to WLm, from the first set voltage, that is, VDN in FIG. 17, to the second set voltage, that is, VSL in FIG. 17, based on the first word line selection signal MWL<1>, the first to m-th driving signals FX<1:m>, and the first to m-th discharge signals FXB<1:m>. The word line driving circuit 314-2 may drive a word line that has been driven to the second set voltage, that is, VSL in FIG. 17, among the first to m-th word lines WL1 to WLm, from the second set voltage, that is, VSL in FIG. 17, to the low voltage, that is, VBBW in FIG. 14, based on the first word line selection signal MWL<1>, the first to m-th driving signals FX<1:m>, and the first to m-th discharge signals FXB<1:m>.

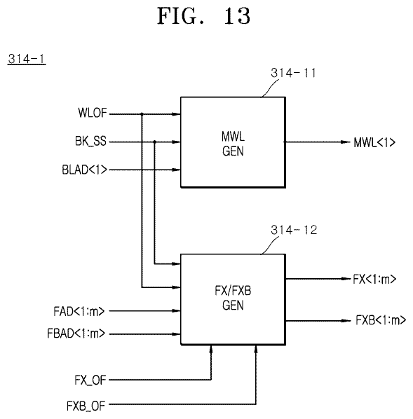

FIG. 13 is a block diagram illustrating a configuration according to an embodiment of the driving signal generation circuit 314-1 included in the word line control circuit 314. The driving signal generation circuit 314-1 may include a word line selection signal generation circuit (MWL GEN) 314-11 and a voltage driving circuit (FX/FXB GEN) 314-12.

The word line selection signal generation circuit 314-11 may generate the first word line selection signal MWL<1> based on a word line off signal WLOF, the bank interval signal BK_SS, and the first bank latch address BLAD<1>. The word line selection signal generation circuit 314-11 may generate the first word line selection signal MWL<1> that is enabled to a logic low level when the bank interval signal BK_SS is enabled to a logic high level and the first bank latch address BLAD<1> is enabled to a logic high level. The word line selection signal generation circuit 314-11 may generate the first word line selection signal MWL<1> that is disabled to a logic high level when the word line off signal WLOF is enabled to a logic high level. The word line off signal WLOF may be set as a signal that is enabled to a logic high level after the start of a precharge operation.

The voltage driving circuit 314-12 may generate the first to m-th driving signals FX<1:m> based on the word line off signal WLOF, the first voltage interval signal FX_OF, and the first to m-th driving addresses FAD<1:m>. The voltage driving circuit 314-12 may generate the first to m-th driving signals FX<1:m> selectively having the voltage level of the high voltage, that is, VPP in FIG. 14, based on the first voltage interval signal FX_OF being enabled to a logic high level and the first to m-th driving addresses FAD<1:m>. The voltage driving circuit 314-12 may generate the first to m-th driving signals FX<1:m> having a voltage level from the voltage level of the high voltage, that is, VPP in FIG. 14, to the voltage level of the ground voltage, that is, VSS in FIG. 14, based on the first to m-th driving addresses FAD<1:m>. The voltage driving circuit 314-12 may generate the first to m-th driving signals FX<1:m> that are disabled to a logic low level when the word line off signal WLOF is enabled to a logic high level.

The voltage driving circuit 314-12 may generate the first to m-th discharge signals FXB<1:m> based on the word line off signal WLOF, the inversion voltage interval signal FXB_OF, and the first to m-th inversion driving addresses FBAD<1:m>. The voltage driving circuit 314-12 may generate the first to m-th discharge signals FXB<1:m> selectively having the voltage level of the high voltage, that is, VPP in FIG. 14, based on the inversion voltage interval signal FXB_OF and the first to m-th inversion driving addresses FBAD<1:m>. The voltage driving circuit 314-12 may generate the first to m-th discharge signals FXB<1:m> having a voltage level from the voltage level of the ground voltage, that is, VSS in FIG. 14, to the voltage level of the high voltage, that is, VPP in FIG. 14, based on the inversion voltage interval signal FXB_OF and the first to m-th inversion driving addresses FBAD<1:m>. The voltage driving circuit 314-12 may generate the first to m-th discharge signals FXB<1:m> that are disabled to a logic low level when the word line off signal WLOF is enabled to a logic high level.

FIG. 14 is a circuit diagram illustrating a configuration according to an embodiment of the word line selection signal generation circuit 314-11 included in the driving signal generation circuit 314-1. The word line selection signal generation circuit 314-11 may include a first driving circuit 314-111 and a second driving circuit 314-112.

When the bank interval signal BK_SS is enabled to a logic high level and the first bank latch address BLAD<1> is enabled to a logic high level, the first driving circuit 314-111 may drive a node ND311 to the ground voltage VSS. When the bank interval signal BK_SS is disabled to a logic low level and the first bank latch address BLAD<1> is disabled to a logic low level, the first driving circuit 314-111 may drive the node ND311 to the high voltage VPP. The first driving circuit 314-111 may drive the node ND311 to the source voltage VDD when the word line off signal WLOF is enabled to a logic high level.

The high voltage VPP may be set as a voltage that is generated from an internal voltage that is used in the semiconductor system 1 and is generated to have a high voltage level through a pumping circuit. The ground voltage VSS may be set as a common ground voltage. The source voltage VDD may be set as a power supply that is supplied by the semiconductor system 1.

The second driving circuit 314-112 may generate the first word line selection signal MWL<1>, which is enabled to a logic low level, by driving the first word line selection signal MWL<1> to the ground voltage VSS when the node ND311 is driven to the ground voltage VSS. The second driving circuit 314-112 may generate the first word line selection signal MWL<1>, which is disabled to a logic high level, by driving the first word line selection signal MWL<1> to the high voltage VPP when the node ND311 is driven to the high voltage VPP. The second driving circuit 314-112 may generate the first word line selection signal MWL<1>, which is disabled to a logic high level, by driving the first word line selection signal MWL<1> to the high voltage VPP when the node ND311 is driven to the source voltage VDD.

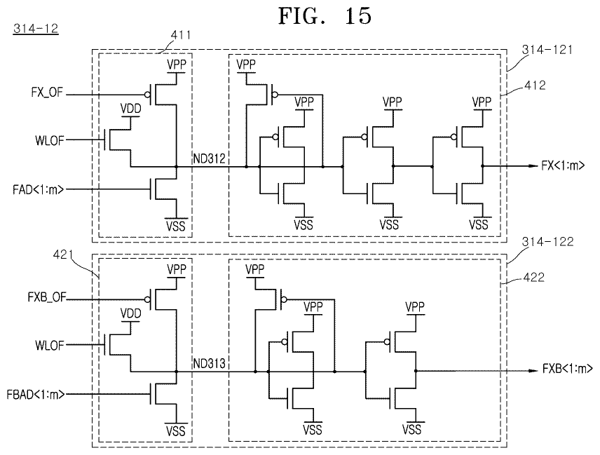

FIG. 15 is a circuit diagram illustrating a configuration according to an embodiment of the voltage driving circuit 314-12 included in the driving signal generation circuit 314-1. The voltage driving circuit 314-12 may include a driving signal generation circuit 314-121 and an discharge signal generation circuit 314-122.

The driving signal generation circuit 314-121 may include a third driving circuit 411 and a fourth driving circuit 412.

When the first voltage interval signal FX_OF is enabled to a logic high level and the first to m-th driving addresses FAD<1:m> are enabled to a logic high level, the third driving circuit 411 may drive a node ND312 to the ground voltage VSS. When the first voltage interval signal FX_OF is disabled to a logic low level and the first to m-th driving addresses FAD<1:m> are disabled to a logic low level, the third driving circuit 411 may drive the node ND312 to the high voltage VPP. The third driving circuit 411 may drive the node ND312 to the source voltage VDD when the word line off signal WLOF is enabled to a logic high level.

The fourth driving circuit 412 may drive the first to m-th driving signals FX<1:m> to the high voltage VPP when the node ND312 is driven to the ground voltage VSS. The fourth driving circuit 412 may drive the first to m-th driving signals FX<1:m> to the ground voltage VSS when the node ND312 is driven to the high voltage VPP. The fourth driving circuit 412 may drive the first to m-th driving signals FX<1:m> to the ground voltage VSS when the node ND312 is driven to the source voltage VDD.

The driving signal generation circuit 314-121, illustrated in FIG. 15, has been illustrated as a single circuit. However, the driving signal generation circuit may be implemented with m circuits, the number of which is the same as the number of bits of the first to m-th driving addresses FAD<1:m>.

The discharge signal generation circuit 314-122 may include a fifth driving circuit 421 and a sixth driving circuit 422.

When the inversion voltage interval signal FXB_OF is enabled to a logic high level and the first to m-th inversion driving addresses FBAD<1:m> are enabled to a logic high level, the fifth driving circuit 421 may drive a node ND313 to the ground voltage VSS. When the inversion voltage interval signal FXB_OF is disabled to a logic low level and the first to m-th inversion driving addresses FBAD<1:m> are disabled to a logic low level, the fifth driving circuit 421 may drive the node ND313 to the high voltage VPP. The fifth driving circuit 421 may drive the node ND313 to the source voltage VDD when the word line off signal WLOF is enabled to a logic high level.

The sixth driving circuit 422 may drive the first to m-th discharge signals FXB<1:m> to the ground voltage VSS when the node ND313 drives the ground voltage VSS. The sixth driving circuit 422 may drive the first to m-th discharge signals FXB<1:m> to the high voltage VPP when the node ND313 is driven to the high voltage VPP. The sixth driving circuit 422 may drive the first to m-th discharge signals FXB<1:m> to the high voltage VPP when the node ND313 is driven to the source voltage VDD.

The discharge signal generation circuit 314-122, illustrated in FIG. 15, has been illustrated as a single circuit. However, the discharge signal generation circuit may be implemented with m circuits the number of which is the same as the number of bits of the first to m-th inversion driving addresses FBAD<1:m>.

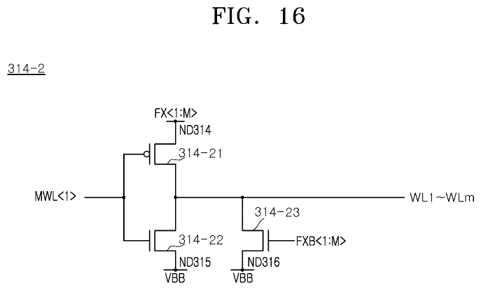

FIG. 16 is a circuit diagram illustrating a configuration according to an embodiment of the word line driving circuit 314-2 included in the word line control circuit 314.

The word line driving circuit 314-2 may be implemented with a first driving element 314-21, a second driving element 314-22, and a third driving element 314-23.

The first driving element 314-21 may be disposed between a node ND314 to which the first to m-th driving signals FX<1:m> are applied and the first to m-th word lines WL1 to WLm. The first driving element 314-21 may drive the first to m-th word lines WL1 to WLm to the voltage level of the first to m-th driving signals FX<1:m> by being turned on when the first word line selection signal MWL<1> is enabled to a logic low level. The first driving element 314-21 may activate any one of the first to m-th word lines WL1 to WLm to the high voltage, that is, VPP in FIG. 14, when the first word line selection signal MWL<1> is enabled to a logic low level and the first to m-th driving signals FX<1:m> are generated to have the high voltage, that is, VPP in FIG. 14. For example, the first driving element 314-21 may activate the first word line WL1 to the high voltage, that is, VPP in FIG. 14, when the first word line selection signal MWL<1> is enabled to a logic low level and the first driving signal FX<1> is generated to have the high voltage, that is, VPP in FIG. 14. The first driving element 314-21 may drive any one of the first to m-th word lines WL1 to WLm from the high voltage, that is, VPP in FIG. 14, to the first set voltage, that is, VDN in FIG. 17, when the first word line selection signal MWL<1> is enabled to a logic low level and the first to m-th driving signals FX<1:m> are generated to have the ground voltage, that is, VSS in FIG. 14. For example, the first driving element 314-21 may drive the first word line WL1 from the high voltage, that is, VPP in FIG. 14, to the first set voltage, that is, VDN in FIG. 17, by discharging the charges of the first word line WL1 to the ground voltage, that is, VSS in FIG. 14, when the first word line selection signal MWL<1> is enabled to a logic low level and the first driving signal FX<1> is generated to have the ground voltage, that is, VSS in FIG. 14.

The second driving element 314-22 may be disposed between the first to m-th word lines WL1 to WLm and a node ND315 to which the low voltage VBBW is applied. The second driving element 314-22 may drive the first to m-th word lines WL1 to WLm to the low voltage VBBW by being turned on when the first word line selection signal MWL<1> is disabled to a logic high level. The second driving element 314-22 may drive a word line that has been driven to the first set voltage, that is, VDN in FIG. 17, from the first set voltage, that is, VDN in FIG. 17, to the second set voltage, that is, VSL in FIG. 17, when the first word line selection signal MWL<1> is disabled to a logic high level. For example, the second driving element 314-22 may drive the first word line WL1 that has been driven to the first set voltage, that is, VDN in FIG. 17, from the first set voltage, that is, VDN in FIG. 17, to the second set voltage, that is, VSL in FIG. 17, by discharging the charges of the first word line WL1 to the low voltage VBBW when the first word line selection signal MWL<1> is disabled to a logic high level.

The third driving element 314-23 may be disposed between the first to m-th word lines WL1 to WLm and a node ND316 to which the low voltage VBBW is applied. The third driving element 314-23 may drive the first to m-th word lines WL1 to WLm to the low voltage VBBW by being turned on when the first to m-th discharge signals FXB<1:m> are generated to have the high voltage VPP. The third driving element 314-23 may drive a word line that has been driven to the second set voltage, that is, VSL in FIG. 17, among the first to m-th word lines WL1 to WLm, from the second set voltage, that is, VSL in FIG. 17, to the low voltage VBBW when the first to m-th discharge signals FXB<1:m> are generated to have the high voltage VPP. For example, the third driving element 314-23 may drive the first word line WL1 that has been driven to the second set voltage, that is, VSL in FIG. 17, from the second set voltage, that is, VSL in FIG. 17, to the low voltage VBBW by discharging the charges of the first word line WL1 to the low voltage VBBW when the first discharge signal FXB<1> is generated to have the high voltage VPP. The low voltage VBBW may be set as a voltage that is generated from an internal voltage that is used in the semiconductor system 1 and may have a low voltage level through the pumping circuit.

FIG. 17 is a timing diagram describing an operation of the word line driving circuit 314-2 according to an embodiment of the present disclosure. An operation of the word line driving circuit 314-2 is described with reference to FIG. 17. In this case, the performing of a soft-landing operation as the first word line WL1 is activated is described as an example as follow.

At timing T11, the first driving element 314-21 of the word line driving circuit 314-2 may be turned on when the first word line selection signal MWL<1> is enabled to a logic low level. The first driving element 314-21 may active the first word line WL1 to the high voltage, that is, VPP in FIG. 14, when the first word line selection signal MWL<1> is enabled to a logic low level and the first driving signal FX<1> is generated to have the high voltage, that is, VPP in FIG. 14.

At timing T12, the first driving element 314-21 of the word line driving circuit 314-2 may drive the first word line WL1 from the high voltage, that is, VPP in FIG. 14, to the first set voltage VDN from timing T12 to timing T13 by discharging the charges of the first word line WL1 to the ground voltage, that is, VSS in FIG. 14, when the first word line selection signal MWL<1> is enabled to a logic low level and the first driving signal FX<1> is generated to have the ground voltage, that is, VSS in FIG. 14.

At timing T13, the second driving element 314-22 of the word line driving circuit 314-2 may be turned on when the first word line selection signal MWL<1> is disabled to a logic high level. The second driving element 314-22 may drive the first word line WL1, which has been driven to the first set voltage VDN, from the first set voltage VDN to the second set voltage VSL from timing T13 to timing T14 by discharging the charges of the first word line WL1 to the low voltage VBBW when the first word line selection signal MWL<1> is disabled to a logic high level.

At timing T14, the third driving element 314-23 of the word line driving circuit 314-2 may drive the first word line WL1, which has been driven to the second set voltage VSL, from the second set voltage VSL to the low voltage VBBW from timing T14 to timing T15 by discharging the charges of the first word line WL1 to the low voltage VBBW when the first discharge signal FXB<1> is generated to have the high voltage VPP.

The semiconductor system 1 according to an embodiment of the present disclosure can prevent a word line that is activated, among the plurality of word lines, from having a floating state by performing a soft-landing operation of sequentially reducing the voltage level of the activated word line. The semiconductor system 1 can prevent a phenomenon in which data are damaged by mitigating the effect of row hammer on an adjacent word line by performing a soft-landing operation of sequentially reducing the voltage level of a word line that is activated, among the plurality of word lines.

What is claimed is:

1. A semiconductor device comprising:
a first driving element configured to drive a word line to a voltage level of a driving signal based on a word line selection signal;
a second driving element configured to drive the word line based on the word line selection signal; and
a third driving element configured to drive the word line based on a discharge signal,
wherein the first driving element drives the word line from a high voltage to a first set voltage when the driving signal having a ground voltage is generated, after driving the word line to the high voltage when the word line selection signal is enabled and the driving signal having the high voltage is generated,
wherein the second driving element drives the word line, which is driven to the first set voltage, to a second set voltage when the word line selection signal is disabled, and
wherein the third driving element drives the word line, which is driven to the second set voltage, to a low voltage when the discharge signal is enabled.

2. The semiconductor device of claim 1,
wherein after the first driving element drives the word line from the high voltage to the first set voltage, the second driving element drives the word line from the first set voltage to the second set voltage, and
wherein after the second driving element drives the word line to the second set voltage, the third driving element drives the word line from the second set voltage to the low voltage.

3. The semiconductor device of claim 1, wherein, when the word line selection signal is enabled and the driving signal is generated to have the ground voltage, the first driving element drives the word line to the first set voltage by discharging charges of the word line.

4. The semiconductor device of claim 1, wherein the second driving element drives the word line from the first set voltage to the second set voltage by discharging charges of the word line when the word line selection signal is disabled.

5. The semiconductor device of claim 1, wherein the third driving element drives the word line from the second set voltage to the low voltage by discharging charges of the word line when the discharge signal is generated to have the high voltage.

6. The semiconductor device of claim 1,
wherein the word line selection signal is a signal that is enabled after a start of an active operation and that is disabled after a start of a precharge operation,
wherein the driving signal is a signal that is generated to have the ground voltage after being generated to have the high voltage after the start of the active operation, and
wherein the discharge signal is a signal that is generated to have the ground voltage after the start of the active operation and that is generated to have the high voltage after the start of the precharge operation.

7. A semiconductor device comprising:
a memory region comprising a plurality of word lines; and
a row control circuit configured to activate any one of the plurality of word lines to a high voltage based on a plurality of row addresses after a start of an active operation and configured to sequentially drive the any one of the plurality of word lines, which is driven to the high voltage, to a first set voltage, a second set voltage, and a low voltage by discharging charges of the any one of the plurality of word lines based on the plurality of row addresses.

8. The semiconductor device of claim 7,
wherein the high voltage is a voltage having a higher voltage level than the first set voltage,
wherein the first set voltage is a voltage having a higher voltage level than the second set voltage, and
wherein the second set voltage is a voltage having a higher voltage level than the low voltage.

9. The semiconductor device of claim 7, wherein the row control circuit:
drives the any one of the plurality of word lines, which is driven to the high voltage, from the first set voltage to the second set voltage, after driving the any one of the plurality of word lines from the high voltage to the first set voltage based on the plurality of row addresses after the start of the active operation, and
drives the any one of the plurality of word lines, which is driven to the second set voltage, from the second set voltage to a low voltage after a start of a precharge operation.

10. The semiconductor device of claim 7, wherein the row control circuit comprises:
an address control circuit configured to generate a first internal active pulse having a pulse width adjusted based on an active command and a precharge command and configured to generate a bank interval signal, a first voltage interval signal, a second voltage interval signal, and an inversion voltage interval signal, each having a pulse width adjusted based on the first internal active pulse and a bank selection signal;
an address latch circuit configured to generate a bank latch address based on a bank address in an interval in which the bank interval signal is enabled and configured to generate a plurality of driving addresses and a plurality of inversion driving addresses, based on the bank selection signal, the bank interval signal, the first voltage interval signal, the second voltage interval signal, the inversion voltage interval signal, and the plurality of row addresses; and
a word line control circuit configured to activate any one of the plurality of word lines based on the plurality of driving addresses and the inversion driving address when the bank latch address is enabled.

11. The semiconductor device of claim 10, wherein the word line control circuit drives the any one of the plurality of word lines to the first set voltage after driving the any one of the plurality of word lines to the high voltage based on the plurality of driving addresses, drives the any one of the plurality of word lines from the first set voltage to the second set voltage, and drives the any one of the plurality of word lines from the second set voltage to the low voltage.

12. The semiconductor device of claim 10, wherein the address control circuit comprises:
an active pulse generation circuit configured to generate an active pulse having a pulse width from a time at which the active command is enabled to a time at which the precharge command is enabled;
a delay control circuit configured to generate the first internal active pulse by delaying the active pulse and adjusting the pulse width of the active pulse, configured to generate a second internal active pulse by delaying the first internal active pulse and adjusting the pulse width of the first internal active pulse, and configured to generate a synthesis pulse signal by synthesizing the first internal active pulse and the second internal active pulse; and
an interval signal generation circuit configured to generate the bank interval signal, the first voltage interval signal, the second voltage interval signal, and the inversion voltage interval signal, based on the bank selection signal, the active pulse, the second internal active pulse, and the synthesis pulse signal.

13. The semiconductor device of claim 12, wherein the delay control circuit comprises:
a first pulse control circuit configured to generate the first internal active pulse by delaying the active pulse and adjusting the pulse width of the active pulse;
a second pulse control circuit configured to generate the second internal active pulse by delaying the first internal active pulse and adjusting the pulse width of the first internal active pulse; and
a third pulse control circuit configured to generate the synthesis pulse signal by synthesizing the first internal active pulse and the second internal active pulse.

14. The semiconductor device of claim 13, wherein the third pulse control circuit is configured to generate the synthesis pulse signal that is enabled when the first internal active pulse is disabled and the second internal active pulse is enabled.

15. The semiconductor device of claim 12, wherein the interval signal generation circuit comprises:
a first logic circuit configured to generate the bank interval signal that is enabled when the synthesis pulse signal is disabled in an interval in which the bank selection signal is enabled;
a second logic circuit configured to generate the first voltage interval signal by buffering the active pulse;
a third logic circuit configured to generate the second voltage interval signal by buffering the second internal active pulse; and
a fourth logic circuit configured to generate the inversion voltage interval signal by buffering the second internal active pulse.

16. The semiconductor device of claim 10, wherein the address latch circuit comprises:
a first address latch circuit configured to generate the bank latch address by latching the bank address in an interval in which the bank selection signal is enabled; and
a second address latch circuit configured to latch the plurality of row addresses in an interval in which the bank selection signal and the bank interval signal are enabled, configured to generate the plurality of driving addresses based on the plurality of row addresses, which is latched, in an interval in which the first voltage interval signal is enabled, and configured to generate the plurality of inversion driving addresses based on the plurality of row addresses, which is latched, in an interval in which the second voltage interval signal is enabled.

17. The semiconductor device of claim 16, wherein the second address latch circuit comprises:
a pre-address generation circuit configured to generate a plurality of pre-addresses by latching the plurality of row addresses in the interval in which the bank selection signal and the bank interval signal are enabled;
a driving address generation circuit configured to generate the plurality of driving addresses based on the plurality of pre-addresses in the interval in which the first voltage interval signal is enabled; and
an inversion driving address generation circuit configured to generate the plurality of inversion driving addresses based on the plurality of pre-addresses in the interval in which the second voltage interval signal is enabled.

18. The semiconductor device of claim 10, wherein the word line control circuit comprises:
a driving signal generation circuit configured to generate a word line selection signal, a plurality of driving signals, and a plurality of discharge signals, based on the bank interval signal, the first voltage interval signal, the inversion voltage interval signal, the plurality of driving addresses, and the inversion driving address; and
a word line driving circuit configured to drive the any one of the plurality of word lines to the first set voltage after driving the any one of the plurality of word lines to the high voltage based on the word line selection signal, the plurality of driving signals, and the plurality of discharge signals, drive the any one of the plurality of word lines from the first set voltage to the second set voltage, and configured to drive the any one of the plurality of word lines from the second set voltage to the low voltage.

19. The semiconductor device of claim 18, wherein the driving signal generation circuit comprises:
a word line selection signal generation circuit configured to generate the word line selection signal that is enabled when the bank interval signal is enabled and the bank latch address is enabled; and
a voltage driving circuit configured to generate the plurality of driving signals having a voltage level from the high voltage to a ground voltage based on the first voltage interval signal and the plurality of driving addresses and configured to generate the plurality of discharge signals having a voltage level from the ground voltage to the high voltage based on the inversion voltage interval signal and the plurality of inversion driving addresses.

20. The semiconductor device of claim 19, wherein the voltage driving circuit comprises:
a driving signal generation circuit configured to generate the plurality of driving signals having the voltage level from the high voltage to the ground voltage, based on the first voltage interval signal being enabled and the plurality of driving addresses; and
a discharge signal generation circuit configured to generate the plurality of discharge signals having the voltage level from the ground voltage to the high voltage, based on the inversion voltage interval signal being enabled and the plurality of inversion driving addresses.
